(19) United States
(12) Patent Application Publication
(10) Pub. No.: US 2025/0253182 A1
(43) Pub. Date: Aug. 7, 2025

(54) METHOD FOR MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Masashi UECHA, Nisshin-shi (JP); Yuji NAGUMO, Nisshin-shi (JP)

(21) Appl. No.: 19/002,878

(22) Filed: Dec. 27, 2024

(30) Foreign Application Priority Data
Feb. 1, 2024 (JP) 2024-014136

(51) Int. Cl. H01L 21/683

(52) U.S. Cl. CPC H01L 21/6836; H01L 2221/68327; H01L 2221/68386

(57) ABSTRACT

A method for manufacturing a semiconductor device includes: performing a treatment on a semiconductor substrate having a retaining tape adhered to a first surface thereof; and dividing the semiconductor substrate by pressing a dividing member against a second surface of the semiconductor substrate, the second surface being opposite to the first surface to which the retaining tape is adhered. An adhesive strength of the retaining tape relative to the first surface is higher in the performing of the treatment than in the dividing of the semiconductor substrate.

### CROSS REFERENCE TO RELATED APPLICATION

The present application claims the benefit of priority from Japanese Patent Application No. 2024-014136 filed on Feb. 1, 2024. The entire disclosures of the above application are incorporated herein by reference.

### TECHNICAL FIELD

The present disclosure relates to a method for manufacturing a semiconductor device.

### BACKGROUND

In a method for manufacturing a semiconductor device, for example, there is a technique for dividing a substrate to which a retaining tape is adhered by pressing a dividing member against a surface of the substrate opposite to a surface to which the retaining tape is adhered.

### SUMMARY

The present disclosure describes a technique for suitably dividing a semiconductor substrate having a retaining tape attached thereto. According to an aspect, a method for manufacturing a semiconductor device includes: performing a treatment on a semiconductor substrate having a retaining tape adhered to a first surface thereof; and dividing the semiconductor substrate by pressing a dividing member against a second surface of the semiconductor substrate having the retaining tape adhered to the first surface, the second surface being opposite the first surface. An adhesive strength of the retaining tape relative to the first surface is higher in the performing of the treatment than in the dividing of the semiconductor substrate.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a cross-sectional view explaining a method for manufacturing a semiconductor device according to an embodiment;

FIG. 2 is a cross-sectional view explaining the method for manufacturing the semiconductor device according to the exemplary embodiment;

FIG. 3A is a plan view of a semiconductor substrate according to the embodiment;

FIG. 3B is a side view of the semiconductor substrate shown in FIG. 3A;

FIG. 4 is a cross-sectional view explaining the method for manufacturing the semiconductor device according to the embodiment;

FIG. 5 is a cross-sectional view explaining the method for manufacturing the semiconductor device according to the embodiment;

FIG. 6 is a cross-sectional view explaining the method for manufacturing the semiconductor device according to the embodiment;

FIG. 7 is a cross-sectional view explaining the method for manufacturing the semiconductor device according to the embodiment;

FIG. 8 is a cross-sectional view explaining the method for manufacturing the semiconductor device according to the embodiment;

FIG. 9 is a cross-sectional view explaining the method for manufacturing the semiconductor device according to the embodiment;

FIG. 10 is a cross-sectional view explaining the method for manufacturing the semiconductor device according to the embodiment;

FIG. 11 is a cross-sectional view explaining the method for manufacturing the semiconductor device according to the embodiment;

FIG. 12 is a cross-sectional view explaining the method for manufacturing the semiconductor device according to the embodiment;

FIG. 13 is a cross-sectional view explaining the method for manufacturing the semiconductor device according to the embodiment;

FIG. 14 is a cross-sectional view explaining the method for manufacturing the semiconductor device according to the embodiment; and

FIG. 15 is a cross-sectional view explaining another example of the method for manufacturing the semiconductor device according to the embodiment.

### DETAILED DESCRIPTION

As a relevant technology, for example, there is a technique for dividing a substrate to which a retaining tape is adhered by pressing a dividing member against a surface of the substrate opposite to a surface to which the retaining tape is adhered.

In such a technique, if an adhesive strength of the retaining tape is strong, the substrate is reinforced by the retaining tape, and it is thus difficult to generate a crack in the substrate when the pressing member is pressed against the substrate. As a result, it is difficult to divide the substrate. On the contrary, if the adhesive strength of the retaining tape is weak, there is a fear that the retaining tape peels off before a step of dividing the substrate.

The present disclosure provides a technique for suitably dividing a semiconductor substrate having a retaining tape attached thereto.

According to a first aspect of the present disclosure, a method for manufacturing a semiconductor device includes: performing a treatment on a semiconductor substrate having a retaining tape adhered to a first surface of the semiconductor substrate; and dividing the semiconductor substrate by pressing a dividing member against a second surface of the semiconductor substrate having the retaining tape adhered to the first surface, the second surface being opposite the first surface. An adhesive strength of the retaining tape relative to the first surface is higher in the performing of the treatment than in the dividing of the semiconductor substrate.

When a semiconductor device is manufactured by the method described above, the adhesive strength of the retaining tape is strong before the dividing of the semiconductor substrate but is weak in the dividing of the semiconductor substrate. Therefore, the semiconductor substrate can be divided suitably in the dividing of the semiconductor substrate.

According to a second aspect of the present disclosure, the method according to the first aspect further includes: decreasing the adhesive strength of the retaining tape after the performing of the treatment and before the dividing of the semiconductor substrate.

According to a third aspect of the present disclosure, in the method according to the first or second aspect, the performing of the treatment includes peeling off the adhesive material adhered to the second surface from the second surface.

According to a fourth aspect of the present disclosure, in the method according to the third aspect, in the performing of the treatment, the adhesive strength of the retaining tape relative to the first surface is higher than an adhesive strength of the adhesive material relative to the second surface.

According to a fifth aspect of the present disclosure, the method according to the third or fourth aspect further includes: attaching a support plate to the second surface via the adhesive material; after the attaching of the support plate, adhering the retaining tape to the first surface; and after the adhering of the retaining tape to the first surface, peeling off the support plate from the adhesive material. Further, the peeling of the adhesive material from the second surface is performed after the peeling of the support plate from the adhesive material, and the dividing of the semiconductor substrate is performed after the peeling of the adhesive material from the second surface.

According to a sixth aspect of the present disclosure, the method according to the fifth aspect further includes: polishing the first surface, after the attaching of the support plate and before the adhering of the retaining tape.

According to a seventh aspect of the present disclosure, in the method according to any one of the first to sixth aspects, the dividing of the semiconductor substrate includes: adhering a protective tape to the second surface; and pressing the dividing member to the second surface via the protective film.

According to an eighth aspect of the present disclosure, the method according to any one of the first to seventh aspects further includes: forming a weak portion linearly distributed in a lateral direction in the semiconductor substrate, before the dividing of the semiconductor substrate.

According to a ninth aspect of the present disclosure, in the method according to the eighth aspect, the forming of the weak portion includes forming a crack in the semiconductor substrate by pressing a pressing member against the semiconductor substrate.

According to a tenth aspect of the present disclosure, in the method according to the eighth aspect, the forming of the weak portion includes forming a modified layer in the semiconductor substrate by applying a laser light to the semiconductor substrate.

According to an eleventh aspect of the present disclosure, in the method according to any one of the first to tenth aspects, the dividing of the semiconductor substrate includes pressing the dividing member against the second surface while supporting a surface of the retaining tape on a side opposite to the semiconductor substrate by an elastic body.

According to the second aspect described above, since the adhesive strength of the retaining tape is strong before the decreasing of the adhesive strength of the retaining tape, it is less likely that the retaining tape and the semiconductor substrate will be separated from each other. After the decreasing of the adhesive strength of the retaining tape, since the adhesive strength of the retaining tape is weak, the semiconductor substrate can be suitably divided in the dividing.

According to the third and fourth aspects described above, it is less likely that the retaining tape will be peeled off from the first surface, when the adhesive material adhered to the second surface is peeled off from the second surface.

The “lateral direction” in the eighth aspect described above is a direction parallel to the second surface of the semiconductor substrate and will also be referred to as a horizontal direction of the semiconductor substrate.

The “modified layer” in the tenth aspect described above is a layer that has been altered by a laser light.

Hereinafter, an embodiment of the present disclosure will be described with reference to the drawings.

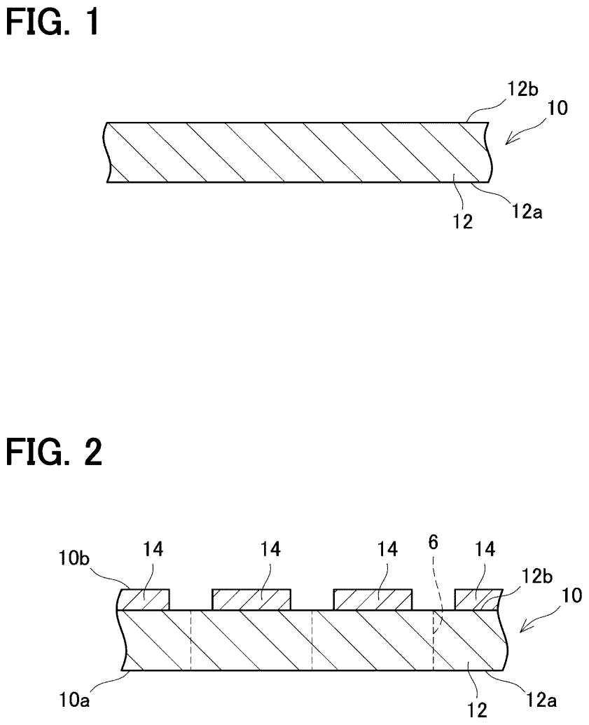

An embodiment relates to a method for manufacturing a semiconductor device from a semiconductor substrate 10 shown in FIGS. 1 through 3B. As shown in FIG. 1, the entire semiconductor substrate 10 before processing is composed of a semiconductor layer 12. The semiconductor layer 12 is made of silicon carbide (SiC) or the like. The semiconductor layer 12 has an upper surface 12b and a lower surface 12a.

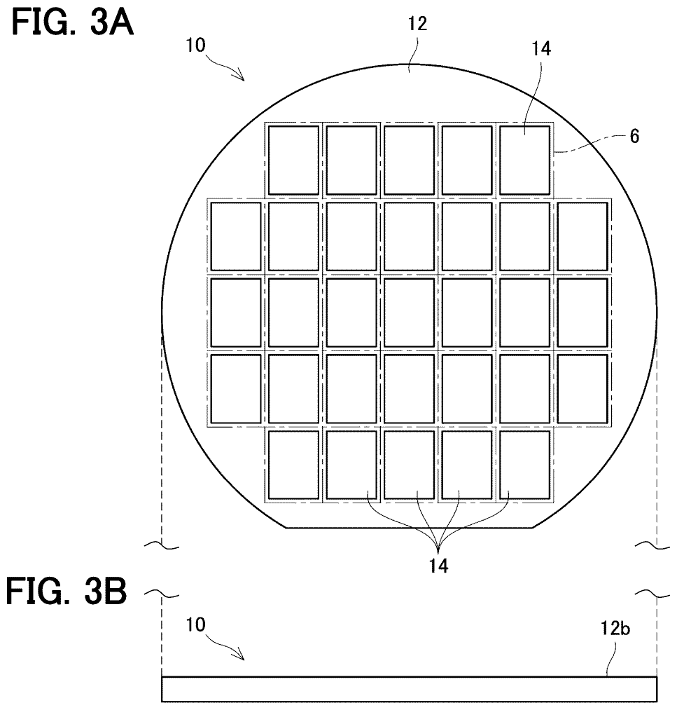

First, an element structure forming step is performed. In the element structure forming step, an element structure, such as a field effect transistor or a diode, is formed in the semiconductor layer 12. Further, as shown in FIGS. 2 and 3A, multiple electrodes 14 are formed on the upper surface 12b of the semiconductor layer 12. In FIG. 3A, planned dividing lines 6 extending in a grid pattern indicate the locations along which the semiconductor substrate 10 will be divided in a later dividing step. The planned dividing lines 6 are not actual lines drawn on the semiconductor substrate 10 but are imaginary lines. The planned dividing lines 6 extend in the grid pattern along the spaces between the electrodes 14. In the following description, the entire substrate including the semiconductor layer 12 and the electrodes provided on the surface of the semiconductor layer 12 will be referred to as the semiconductor substrate 10. In addition, an upper surface of the semiconductor substrate 10 (e.g., in FIG. 2, the surfaces of the electrodes 14 and the upper surface 12b of the semiconductor layer 12) is referred to as a second surface 10b of the semiconductor substrate 10, and a lower surface of the semiconductor substrate 10 (e.g., in FIG. 2, the lower surface 12a of the semiconductor layer 12) is referred to as a first surface 10a of the semiconductor substrate 10.

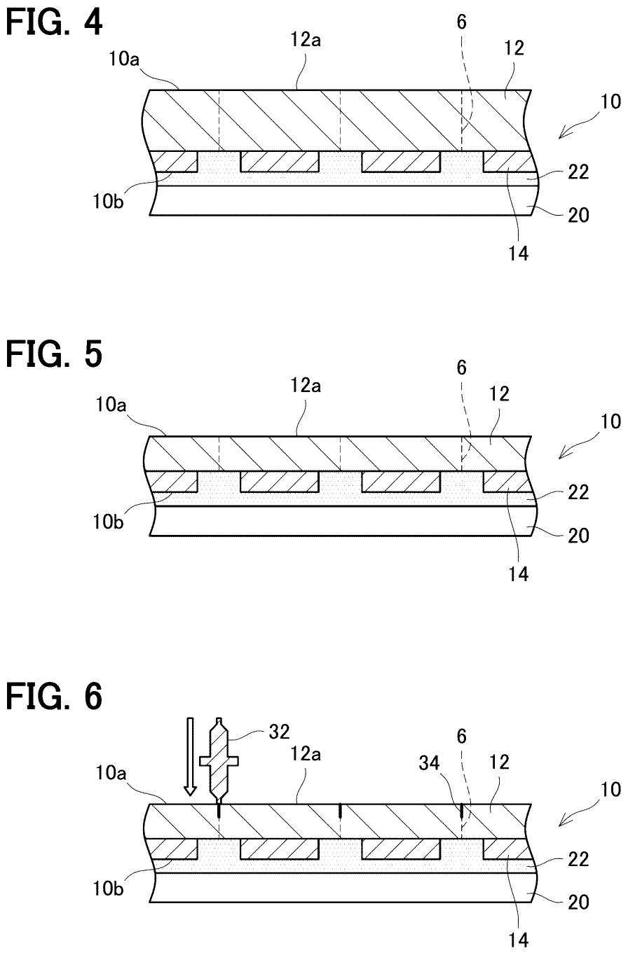

Next, a support plate attaching step is performed. As shown in FIG. 4, in the support plate attaching step, a support plate 20 is attached to the second surface 10b of the semiconductor substrate 10. It should be noted that, in FIGS. 4 to 7, the semiconductor substrate 10 is depicted with the second surface 10b facing downward. The support plate 20 is attached to the second surface 10b via an adhesive material 22. In other words, the adhesive material 22 bonds the support plate 20 and the second surface 10b of the semiconductor substrate 10 to each other. The support plate 20 is made of, for example, a glass plate. The adhesive material 22 is made of, for example, a silicon-based adhesive.

Next, a polishing step is performed. As shown in FIG. 5, in the polishing step, the first surface 10a of the semiconductor substrate 10 (i.e., the lower surface 12a of the semiconductor layer 12) is polished to thin the semiconductor layer 12.

Next, a weak portion forming step is performed. As shown in FIG. 6, in the weak portion forming step, a scribing wheel 32, which serves as a pressing member, is pressed against the first surface 10a of the semiconductor substrate 10. The scribing wheel 32 is a disk-shaped member and is axially supported by a supporting device (not shown). In addition, the scribing wheel 32 is rotatable. The scribing wheel 32 has a structure with a sharp outer circumferential edge but does not cut the semiconductor substrate 10. That is, the scribing wheel 32 is simply pressed against the first surface 10a. In the weak portion forming step, the scribing wheel 32 is moved so as to roll while being pressed against the first surface 10a of the semiconductor substrate 10. As shown in FIG. 6, when the scribing wheel 32 is moved, a crack 34 extending in a thickness direction of the semiconductor substrate 10 is formed. The crack 34 is formed in a range near the first surface 10a, that is, in a surface layer of the semiconductor substrate 10 on the first surface 10a side. In this case, the scribing wheel 32 is moved along each of the planned dividing lines 6 shown in FIG. 3A, thereby to form the crack 34 along each of the planned dividing lines 6.

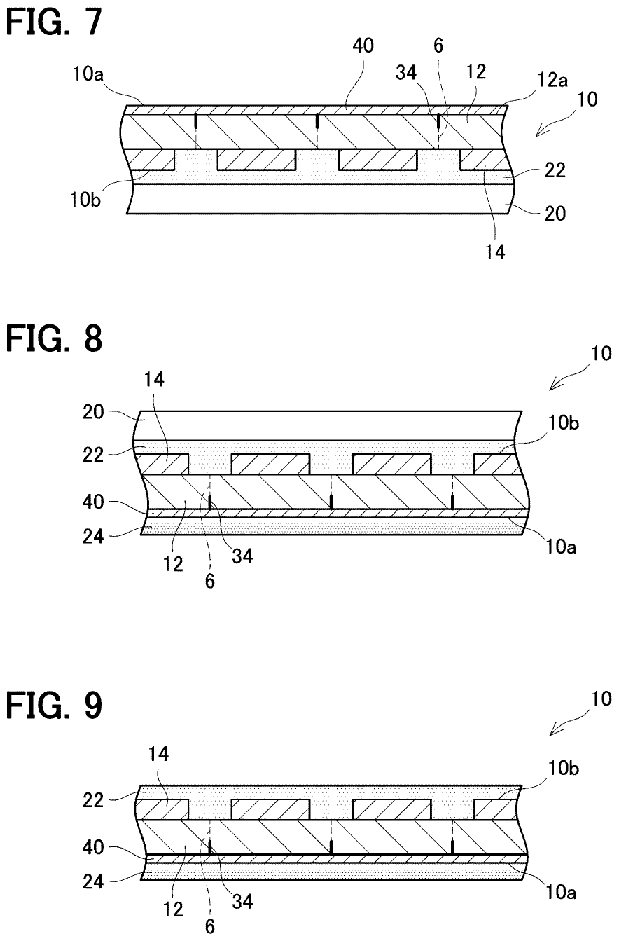

Next, an electrode forming step is performed. As shown in FIG. 7, in the electrode forming step, an electrode 40 is formed on the lower surface 12a of the semiconductor layer 12. The electrode 40 is made of a multi-layer film in which, for example, titanium, nickel, and gold are laminated.

Next, a retaining tape adhering step is performed. As shown in FIG. 8, in the retaining tape adhering step, a retaining tape 24 is adhered to the first surface 10a of the semiconductor substrate 10, that is, the surface of the electrode 40. In FIG. 8 and subsequent figures, the semiconductor substrate 10 is illustrated with the second surface 10b of the semiconductor substrate 10 facing up. The retaining tape 24 is, for example, a dicing tape. The outer periphery of the retaining tape 24 is fixed by a frame (not shown). The adhesive strength between the retaining tape 24 and the first surface 10a of the semiconductor substrate 10 is higher than the adhesive strength between the adhesive material 22 and the second surface 10b of the semiconductor substrate 10.

Next, a support plate peeling step is performed. As shown in FIG. 9, in the support plate peeling step, the support plate 20 is peeled off from the adhesive material 22.

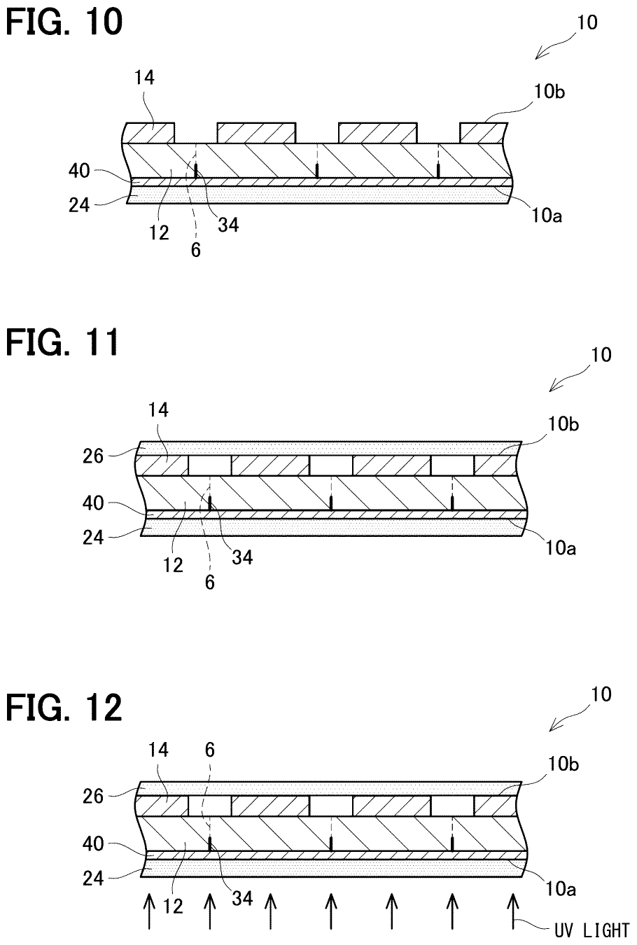

Next, an adhesive material peeling step is performed. As shown in FIG. 10, in the adhesive material peeling step, the adhesive material 22 is pulled upward to be removed from the second surface 10b of the semiconductor substrate 10. The adhesive strength between the adhesive material 22 and the second surface 10b of the semiconductor substrate 10 is lower than the adhesive strength between the retaining tape 24 and the first surface 10a. Therefore, when the adhesive material 22 is peeled off from the semiconductor substrate 10, the retaining tape 24 is not peeled off from the semiconductor substrate 10. That is, the retaining tape 24 is maintained in a state of being adhered to the semiconductor substrate 10.

Next, a protective tape adhering step is performed. As shown in FIG. 11, in the protective tape adhering step, a protective tape 26 is adhered to the second surface 10b of the semiconductor substrate 10.

Next, an adhesive strength decreasing step is performed. As shown in FIG. 12, in the adhesive strength decreasing step, an ultraviolet (UV) light is applied to the retaining tape 24 from the lower side of the retaining tape 24. By irradiating the retaining tape 24 with the UV light, the adhesive strength between the retaining tape 24 and the first surface 10a is decreased.

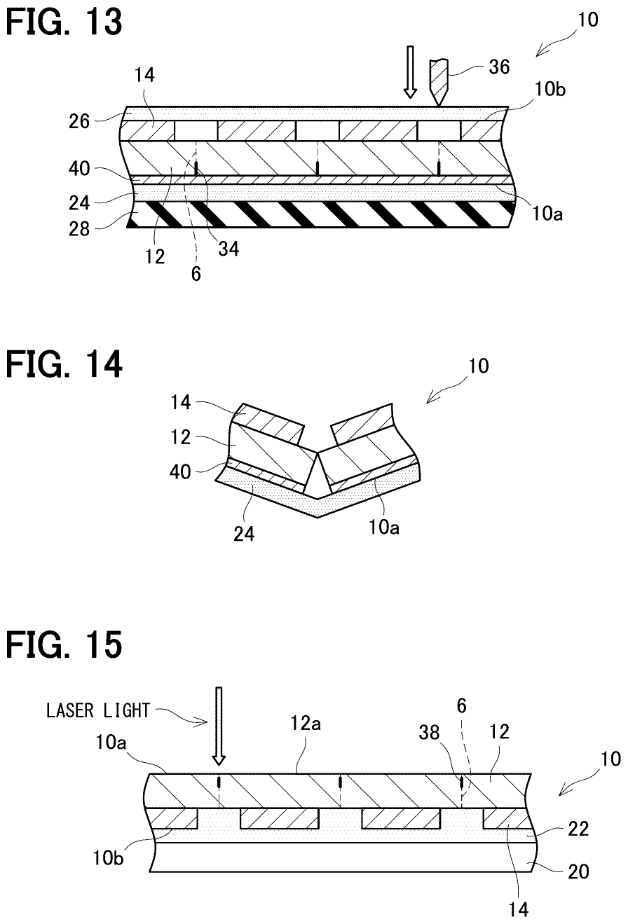

Next, a dividing step is performed. As shown in FIG. 13, in the dividing step, the semiconductor substrate 10 is placed on a support base 28 so that the exposed surface of the retaining tape 24 (i.e., the surface of the retaining tape 24 opposite to the semiconductor substrate 10) is in contact with the support base 28. The surface layer of the support base 28 is made of an elastic material (e.g., rubber). Next, a braking bar 36, which serves as a dividing member, is pressed against the second surface 10b of the semiconductor substrate 10 via the protective tape 26. The braking bar 36 is a plate-shaped member. Although the lower end of the breaking bar 36 has a sharp structure, the breaking bar 36 does not cut the semiconductor substrate 10. That is, the breaking bar 36 is simply pressed against the semiconductor substrate 10. Here, the breaking bar 36 is pressed against the second surface 10b along the planned dividing line 6. When the breaking bar 36 is pressed against the second surface 10b, the crack 34 extends in the thickness direction of the semiconductor substrate 10. As a result, the semiconductor substrate 10 is cleaved from the crack 34 as a starting point, and the semiconductor substrate 10 is thus divided.

As shown in FIG. 14, when the semiconductor substrate 10 is divided, the retaining tape 24 is stretched at the dividing position (i.e., below the breaking bar 36). At the position where the retaining tape 24 is stretched, the retaining tape 24 slides against the first surface 10a of the semiconductor substrate 10.

If the adhesive strength of the retaining tape 24 is too high, the retaining tape 24 cannot slide against the first surface 10a, and the stretching of the retaining tape 24 is restricted. Therefore, if the adhesive strength of the holding tape 24 is too high, the semiconductor substrate 10 cannot be appropriately divided.

In contrast, in the present embodiment, since the adhesive strength decreasing step is performed before the dividing step, the adhesive strength between the retaining tape 24 and the first surface 10a is low in the dividing step. Therefore, the retaining tape 24 easily slides relative to the first surface 10a in the vicinity of the dividing position, and the retaining tape 24 easily stretch at the dividing position. As a result, the cleavage of the semiconductor substrate 10 enhanced, and the semiconductor substrate 10 can be suitably divided. The chips divided from the semiconductor substrate 10 are semiconductor devices.

As described above, in the present embodiment, since the adhesive strength of the retaining tape 24 is high at the stage of the adhesive material peeling step, the adhesive material 22 can be appropriately peeled off from the semiconductor substrate 10 in the adhesive material peeling step. Further, since the dividing step is performed after the adhesive strength decreasing step, the retaining tape 24 can easily slide against the first surface 10a in the dividing step. Therefore, the semiconductor substrate 10 can be appropriately divided.

In the embodiment described above, in the weak portion forming step, the crack 34, that is, the weak portion is formed by the scribing wheel 32. As another example, as shown in FIG. 15, in the weak portion forming step, a modified layer 38 may be formed in the semiconductor substrate 10 by irradiating the semiconductor substrate 10 with a laser light. In FIG. 15, the laser light is focused inside the semiconductor substrate 10. The portion of the semiconductor substrate 10 on which the laser light is focused is altered by the laser light, and hence a modified layer 38 is formed in the portion where the laser light is focused. The modified layer 38 corresponds to the weak portion having a strength weaker than that of the surrounding semiconductor layer 12. In the dividing step, the cleavage occurs starting from the modified layer 38.

In the embodiment described above, the weak portion forming step is performed after the polishing step and before the electrode forming step. However, the weak portion forming step may be performed at any time before the dividing step.

In the embodiment described above, the adhesive material 22 is, for example, a silicon-based adhesive. However, the adhesive material 22 may be provided be a double-sided tape that bonds the support plate 20 and the semiconductor substrate 10.

In the embodiment described above, the polishing step is performed after the support plate attaching step and before the weak portion forming step. However, the polishing step may be performed at any time after the support plate attaching step and before the retaining tape adhering step.

In the embodiment described above, the adhesive strength decreasing step is a step of decreasing the adhesive strength between the retaining tape 24 and the first surface 10a by the irradiation with the UV light. As another example, in the adhesive strength decreasing step, the adhesive strength may be decreased by applying heat to the retaining tape 24.

In the embodiment described above, the step of peeling off the adhesive material 22 is performed as a step of performing a treatment on the semiconductor substrate 10 (hereinafter, referred to as the treatment performing step). However, as the treatment of the treatment performing step, another process or treatment, such as, plating of electrodes, or electrical inspection of semiconductor elements, may be performed. Even in such a treatment performing step, since the adhesive strength of the retaining tape 24 is high, it is possible to suppress the retaining tape 24 from peeling off during the treatment performing step.

In the embodiment described above, the dividing step is performed after the treatment performing step. Alternatively, the treatment performing step may be performed after the dividing step.

Although the embodiment and examples thereof have been described in detail above, these are merely examples and do not limit the scope of claims. The techniques described in the claims include various modifications and modifications of the specific examples illustrated above. The technical elements described in the present specification, or the drawings exhibit technical usefulness alone or in various combinations and are not limited to the combinations described in the claims at the time of filing. In addition, the techniques illustrated in the present specification or drawings achieve multiple objectives at the same time, and achieving one of the objectives itself has technical usefulness.

What is claimed is:

1. A method for manufacturing a semiconductor device, the method comprising:
performing a treatment on a semiconductor substrate having a retaining tape adhered to a first surface of the semiconductor substrate; and
dividing the semiconductor substrate by pressing a dividing member against a second surface of the semiconductor substrate, the second surface being opposite to the first surface to which the retaining tape is adhered, wherein
an adhesive strength of the retaining tape relative to the first surface is higher in the performing of the treatment than in the dividing of the semiconductor substrate.

2. The method according to claim 1, further comprising:
decreasing the adhesive strength of the retaining tape after the performing of the treatment and before the dividing of the semiconductor substrate.

3. The method according to claim 1, wherein
the performing of the treatment includes peeling off an adhesive material adhering to the second surface from the second surface.

4. The method according to claim 3, wherein
in the performing of the treatment, the adhesive strength of the retaining tape relative to the first surface is higher than an adhesive strength of the adhesive material relative to the second surface.

5. The method according to claim 3, further comprising:
attaching a support plate to the second surface via the adhesive material;
adhering the retaining tape to the first surface, after the attaching of the support plate; and
peeling off the support plate from the adhesive material, after the adhering of the retaining tape to the first surface, wherein
the peeling of the adhesive material from the second surface is performed after the peeling of the support plate from the adhesive material, and
the dividing of the semiconductor substrate is performed after the peeling of the adhesive material from the second surface.

6. The method according to claim 5, further comprising:
polishing the first surface, after the attaching of the support plate and before the adhering of the retaining tape.

7. The method according to claim 1, wherein
the dividing of the semiconductor substrate includes:
adhering a protective tape to the second surface; and
pressing the dividing member against the second surface via the protective tape.

8. The method according to claim 1, further comprising:
forming a weak portion distributed linearly in a lateral direction in the semiconductor substrate, before the dividing of the semiconductor substrate.

9. The method according to claim 8, wherein
the forming of the weak portion includes forming a crack in the semiconductor substrate by pressing a pressing member against the semiconductor substrate.

10. The method according to claim 8, wherein
the forming of the weak portion includes forming a modified layer in the semiconductor substrate by applying a laser light to the semiconductor substrate.

11. The method according to claim 1, wherein
the dividing of the semiconductor substrate includes pressing the dividing member against the second surface while supporting a surface of the retaining tape on a side opposite to the semiconductor substrate by an elastic body.
